(19) United States
(12) Patent Application Publication
(10) Pub. No.: US 2003/0209790 A1
(43) Pub. Date: Nov. 13, 2003

(54) Semiconductor memory module

(75) Inventors: Yasuhiro Matsumoto, Hyogo (JP); Hiromi Okimoto, Hyogo (JP); Yasuhiro Kashiwazaki, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/243,655

(22) Filed: Sep. 16, 2002

(30) Foreign Application Priority Data
May 13, 2002 (JP) 2002-136781 (P)

(51) Int. Cl. H01L 21/44; H01L 21/48; H01L 21/50; H01L 23/02

(52) U.S. Cl. 257/678

(57) ABSTRACT

A jumper circuit is provided for enabling the switching of the mode in the case that a bare chip is detected as being defective, wherein data that has been inputted to/outputted from a bare chip detected as being defective is inputted to/outputted from a good function chip for repair mounted on the rear surface of a module substrate so that the good function chip functions in place of the bare chip that has been detected as being defective. Thereby, a semiconductor memory module is obtained that can be repaired in the case that a bare chip is detected as being defective from among a plurality of bare chips while effectively utilizing bare chips other than the bare chip that has become defective from among the plurality of bare chips.

### BACKGROUND OF THE INVENTION

1. Field of the Invention

The present invention relates to a semiconductor memory module wherein semiconductor chips are mounted on a module substrate.

2. Description of the Background Art

A semiconductor memory device is, in many cases, utilized in a personal computer, a workstation or the like. In addition, in recent years the speed, degree of compactness and number of functions of personal computers have increased and, therefore, semiconductor memory devices have been required to further increase their memory capacity. In addition, the market has expanded so that a large number of low-cost memory devices are used. Therefore, further increase in the capacity of and further reduction in costs of semiconductor memory devices have become required.

The number of DRAMs (Dynamic Random Access Memory), from among the above described semiconductor memory devices, utilized in personal computers or the like has increased because it is advantageous from the point of view of cost per bit unit. Cost per bit unit can be reduced by increasing the diameter of wafers even in the case that the capacity is increased and, therefore, DRAMs are frequently utilized.

In a DRAM, however, cost of development, cost for high level institutions and the like have greatly increased together with the increase in the testing period of time and test costs accompanying the increase in capacity as well as the enhancement of microscopic processing technology so that whether or not those costs can be reduced has become a problem.

The bit configuration for the input to or output from a DRAM is conventionally 4 bits, 8 bits or 16 bits. Accordingly, the variety in types of bit numbers of a DRAM is small. Therefore, one module is normally made up of a plurality of DRAMs for general utilization. Thus, a semiconductor memory device such as a DRAM is, in many cases, utilized in a module condition.

FIGS. 16 and 17 show an example of a conventional semiconductor memory module. The conventional semiconductor module has a structure, wherein single chips 117, in which bare chips 101, mounting islands 104, bonding wires 105 and lead frames 110 are molded into mold resin 108, are mounted on a module substrate 102, such as of an SOP (Small Outline Package) or a TSOP (Thin Small Outline Package) corresponding to a surface mounting technology wherein parts can be mounted on both sides of a printed circuit board.

In addition, development has progressed of a memory package having a basic tendency toward miniaturization and thinning together with enhancement of performance and of functions of a memory chip. Then, though an insertion system has been adopted for a memory package, in recent years the forms of packages have greatly changed such that a surface mounting system has started to be adopted.

At present, the surface mounting system has become the main trend in place of the insertion system and further miniaturization and lightening of a package are strongly required. Up to the present, simplification of design and increase in reliability, as well as reduction in cost, have been achieved by utilizing a semiconductor memory module.

In addition, in a conventional manufacturing process of a semiconductor memory module, in the case that a defective chip is discovered in a module test after the manufacture of a semiconductor memory module, testing and replacement of such a defective chip are carried out until such defect has been removed.

There is a problem wherein a great amount of time and effort are required for the replacement of a memory chip that has been detected as being defective according to the conventional manufacturing process of a semiconductor memory module. Furthermore, there is a memory module in the form of a COB (Chip On Board) as a semiconductor memory module that can solve this problem.

According to the conventional module in the form of a COB, however, there is a problem wherein a bare chip that has been detected as being defective cannot be repaired after bare chips have been sealed into a mold resin.

As a result, a semiconductor memory module having a bare chip that has become defective needs to be discarded even in the case that bare chips other than the defective bare chip, from among the plurality of bare chips, function properly. Thereby, the yield of the semiconductor memory module is lowered.

### SUMMARY OF THE INVENTION

An object of the present invention is to provide a semiconductor memory module wherein bare chips other than the bare chip that has become defective from among a plurality of bare chips are effectively utilized so that the yield can be increased.

A semiconductor memory module of the present invention is provided with a module substrate, a plurality of bare chips mounted on a main surface of the module substrate, and a plurality of good function chip (non defective chip; The chip functions without any a problem in usual use) mounting regions on which, in the case that one or plural bare chips from among the plurality of bare chips are detected as being defective, one or plural good function chips that function in place of the one or plural bare chips that have been detected as being defective can be mounted.

In addition, the semiconductor memory module is provided with a switching circuit that, in the case that one or plural good function chips are mounted in one or plural regions from among the plurality of good function chip mounting regions, can convert a mode wherein data is inputted to/outputted from the one or plural bare chips that have been detected as being defective to a mode wherein the data is inputted to/outputted from the good function chips mounted in the good function chip mounting regions.

According to the above described configuration, the mode of the switching circuit can be converted so that the input/output of data to/from the good function chips is not obstructed by the bare chips that have been detected as being defective. Thereby, the semiconductor memory module can be repaired by using good function chips. As a result, the yield of the semiconductor memory module can be increased.

A semiconductor memory module according to another aspect of the present invention is provided with a module substrate, a plurality of bare chips mounted on the module substrate, and a plurality of substrate input/output terminals mounted on the module substrate, to which a plurality of chip input/output terminals for inputting/outputting data from/to bare chips, respectively, is electrically connected in a one-to-one manner. In addition, the above described plurality of bare chips includes an unconnected bare chip of which the plurality of chip input/output terminals is not electrically connected to any of the plurality of substrate input/output terminals.

According to the above described configuration, the semiconductor memory module includes an unconnected bare chip and this indicates that a spare bare chip or a defective bare chip that is substituted for by a spare bare chip is included in the plurality of bare chips.

Therefore, according to the above described semiconductor memory module, the semiconductor memory module can be manufactured by a manufacturing method wherein, in the case that the presence of a defective bare chip is detected from among the plurality of bare chips as a result of a system examination after the plurality of bare chips has been mounted on the module substrate, a spare bare chip from among the plurality of bare chips is used to repair the semiconductor memory module. As a result, the yield of the semiconductor memory module can be increased.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a condition wherein a plurality of bare chips mounted on a module substrate is electrically connected to data input/output terminals provided on the module substrate, respectively, in a semiconductor memory module of a first embodiment;

FIG. 2 is a view for describing bare chips mounted on the module substrate of the semiconductor memory module of the first embodiment;

FIG. 3 is a view for describing a cross sectional structure of a bare chip and a repair chip mounted on the module substrate of the semiconductor memory module of the first embodiment;

FIG. 4 is a view for describing that one of the bare chips mounted on the module substrate of the semiconductor memory module of the first embodiment has become defective products;

FIG. 5 is a view for describing that the semiconductor memory module is repaired by utilizing a good function chip mounted on the rear surface of the module substrate of the semiconductor memory module of the first embodiment;

FIG. 6 is a diagram for describing a configuration of a module substrate before repair of semiconductor memory modules of the first and second embodiments;

FIG. 7 is a diagram for describing a configuration of a module substrate after repair of semiconductor memory modules of the first and second embodiments;

FIG. 8 is a view for describing the mounting position of a jumper circuit of the semiconductor memory module of the first embodiment;

FIG. 9 is a view for describing a configuration on the front surface of a module substrate after repair of the semiconductor memory module of the first embodiment;

FIG. 10 is a view for describing a configuration on the rear surface of a module substrate after repair of the semiconductor memory module of the first embodiment;

FIG. 11 is a diagram for more concretely describing a configuration on the rear surface of the module substrate before repair of the semiconductor memory module of the first embodiment;

FIG. 12 is a diagram for more concretely describing a configuration on the rear surface of the module substrate after repair of the semiconductor memory module of the first embodiment;

FIG. 13 is a diagram for describing a condition before a defective bare chip is detected in a semiconductor memory module of the second embodiment;

FIG. 14 is a diagram for describing a condition wherein bare chips of the semiconductor memory module of the second embodiment are not integrally molded in a mold resin;

FIG. 15 is a diagram for describing a condition after the bare chips of the semiconductor memory module of the second embodiment are integrally molded in a mold resin;

FIG. 16 is a view for describing a configuration seen from above of a semiconductor memory module according to a prior art; and

FIG. 17 is a view for describing a cross sectional configuration of the semiconductor memory module according to the prior art.

### DESCRIPTION OF THE PREFERRED EMBODIMENTS

(First Embodiment)

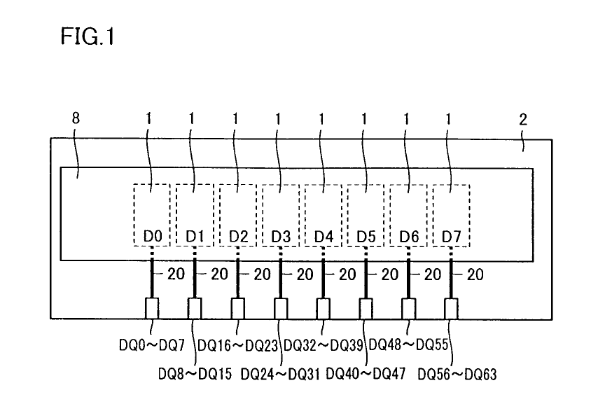

In the following, a semiconductor memory module, which is repairable after bare chips have been covered with a mold resin, according to the first embodiment of the present invention will be described in reference to FIGS. 1 to 12.

The semiconductor memory module of the present embodiment is repaired, in the case that a molded bare chip is detected as being defective, by mounting, on the module substrate, a repair chip that carries out the functions so as to substitute for the bare chip that has been detected as being defective.

FIG. 1 shows the semiconductor memory module of the embodiment. As shown in FIG. 1, in the semiconductor memory module of the embodiment, a plurality of bare chips 1 is directly mounted on one of the main surfaces of a module substrate 2 and the plurality of bare chips 1 is integrally molded into a mold resin 8.

In addition, data input/output terminals of the plurality of bare chips, respectively, are provided on module substrate 2 and are electrically connected to data input/output terminals DQ0 to DQ7, DQ8 to DQ15, DQ16 to DQ23, DQ24 to DQ31, DQ32 to DQ39, DQ40 to DQ47, DQ48 to DQ55 and DQ56 to DQ63 for inputting/outputting data stored in memory regions inside of bare chips 1 from/to the outside of the module substrate.

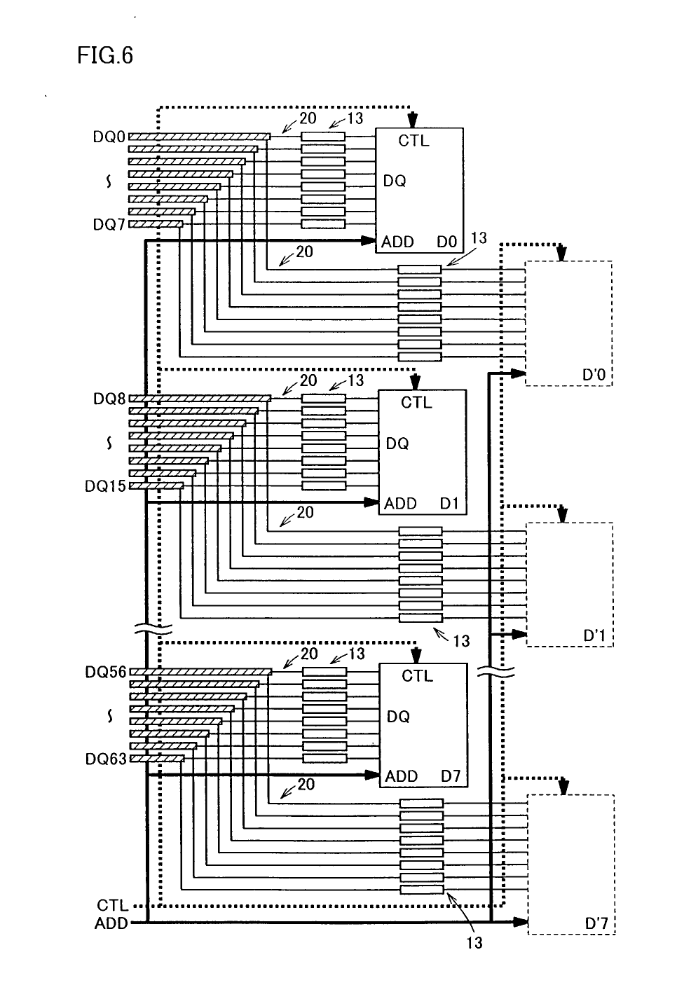

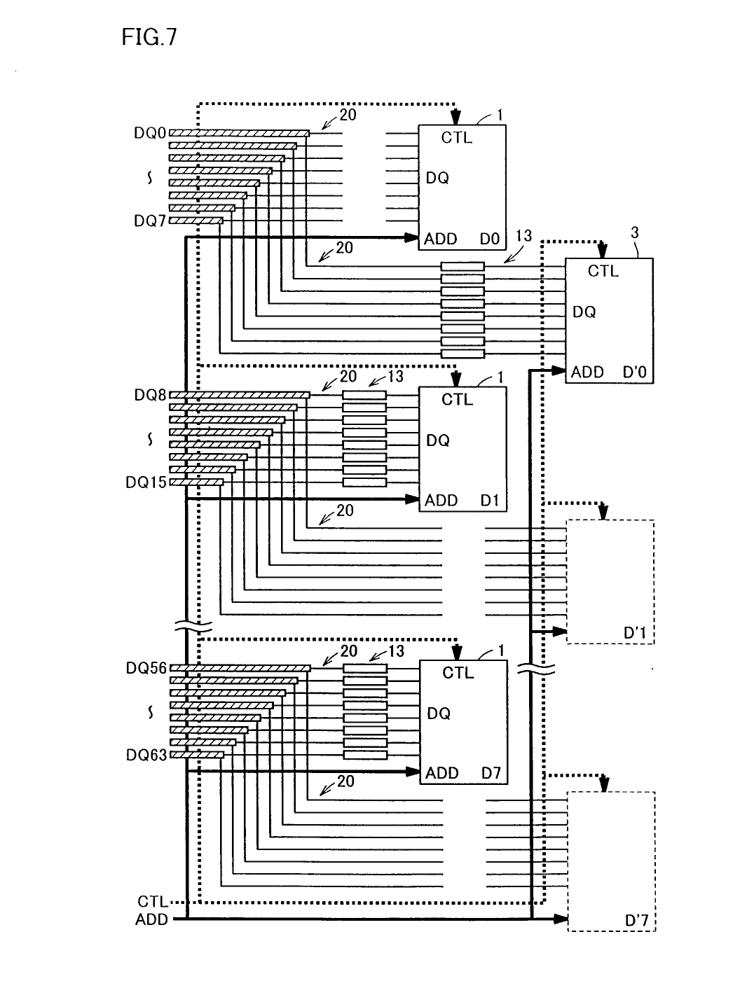

Here, data input/output terminals DQ0 to DQ7, DQ8 to DQ15, DQ16 to DQ23, DQ24 to DQ31, DQ32 to DQ39, DQ40 to DQ47, DQ48 to DQ55 and DQ56 to DQ63, respectively, are depicted as single data input/output terminals in FIG. 1. In actuality, however, as shown in FIGS. 6 and 7, there are eight data input/output terminals, connected to eight data lines, respectively, in a one-to-one manner, that are connected to eight data input/output terminals of a bare chip 1 per one data input/output terminal DQ shown in FIG. 1.

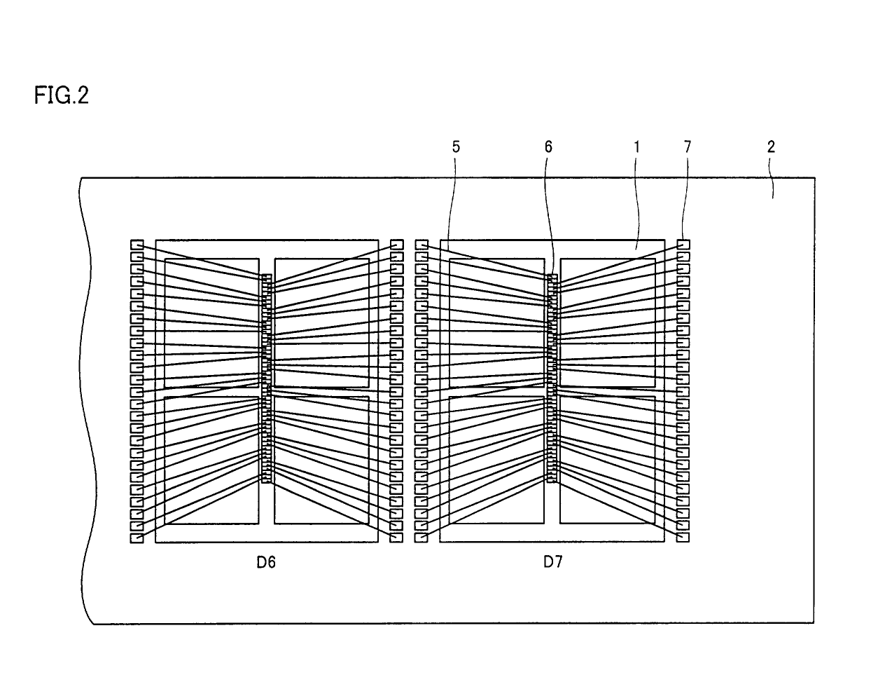

In addition, as shown in FIG. 2, chip bonding pads 6 provided on bare chips 1 and wiring pads 7 provided on module substrate 2 are connected by means of bonding wires 5.

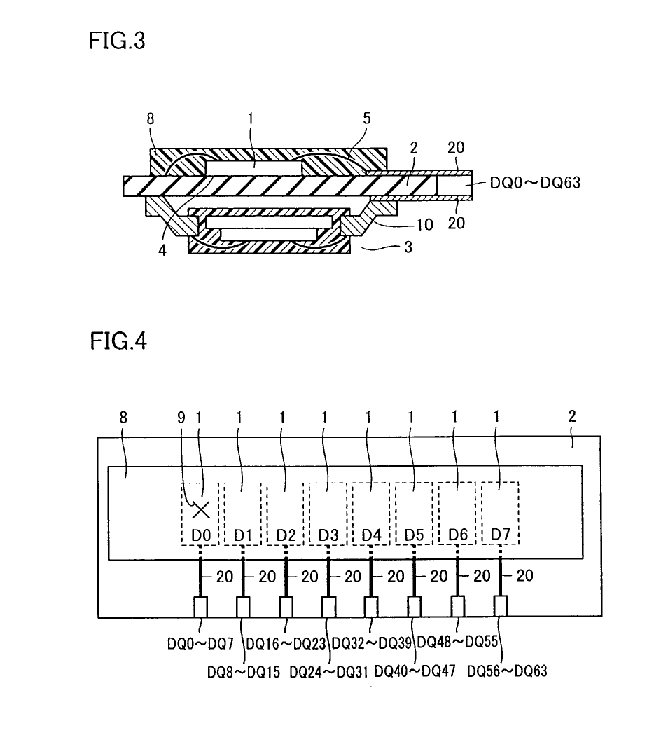

In addition, the semiconductor memory module of the embodiment has a structure wherein, in the case that any bare chip 1 from among the plurality of bare chips 1 is detected as being defective, as shown in FIG. 3, a good function chip 3 used in place of bare chip 1 can be mounted on the rear side of the main surface on which the plurality of bare chips 1 is provided.

In addition, as shown in FIGS. 3, 6 and 7, electrical wires 20 electrically connected to a bare chip 1 and electrical wires 20 electrically connected to a good function chip 3 as a repair chip used in place of this bare chip 1 are separately wired on the front surface and on the rear surface of module substrate 2, and then, are electrically connected to common data input/output terminals DQ, respectively.

According to a manufacturing method for a semiconductor memory module of the present embodiment, as shown in FIG. 2, after a plurality of bare chips 1 is mounted on a module substrate 2, chip bonding pads 6 provided on bare chips 1 and wiring pads 7 provided on module substrate 2 are electrically connected by means of bonding wires 5.

After that, as shown in FIG. 3, the plurality of bare chips 1 is integrally molded into a mold resin 8, thereby a semiconductor memory module is completed. Then, the semiconductor memory module has a structure wherein, after the completion of the semiconductor memory module, a molded good function chip 3 can be mounted on the rear surface of module substrate 2 if necessary.

Therefore, in the case that a defective product is detected from among the plurality of bare chips 1 by means of a variety of tests such as a system test after the semiconductor memory module is manufactured, a good function chip 3 is mounted on the rear surface of module substrate 2 so that good function chip 3 carries out the functions of bare chip 1 that has become defective, thereby it becomes possible to repair the semiconductor memory module.

Here, in order for good function chip 3 to carry out the functions of bare chip 1 that has been detected as being a defective product, it is necessary to prevent bare chip 1 that has been detected as being a defective product from inputting/outputting data to/from a data input/output terminal DQ.

In the semiconductor memory module of the present embodiment, a resistance element making an electrical connection between bare chip 1 that has been detected as being defective and data input/output terminal DQ is appropriately removed, thereby bare chip 1 that has been detected as being defective is prevented from outputting/inputting data to/from data input/output terminal DQ. Here, a concrete technique for removing the resistance element making an electrical connection between bare chip 1 that has been detected as being defective and data input/output terminal DQ will be described below.

In addition, in the semiconductor memory module of the embodiment, the plurality of bare chips 1 on module substrate 2 is integrally molded into mold resin 8. Therefore, the mounting area of the semiconductor memory module can be made small.

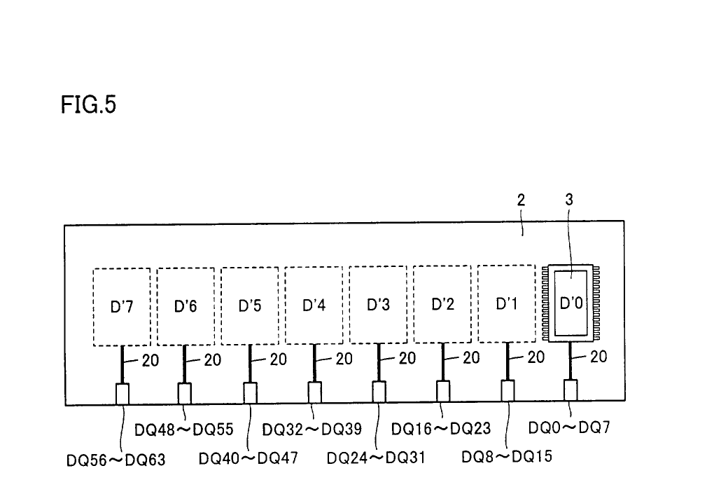

FIGS. 4 and 5 show a configuration example of a module substrate after repair. As shown in FIGS. 4 and 5, in the semiconductor memory module, bare chips 1 (D0 to D7) are mounted on the front surface of module substrate 2 and good function chip mounting provision regions for good function chips 3 (D′0 to D′7) mounted at the time of repair is provided on the rear surface.

FIG. 6 shows a block diagram of the front surface and of the rear surface of module substrate 2 on which bare chips 1 (D0 to D7) are mounted before repair. FIG. 7 shows a block diagram of the front surface and of the rear surface of module substrate 2 on which single good function chips 3 (D′0 to D′7) in molds, which are utilized at the time of repair, are mounted.

As shown in FIGS. 6 and 7, the semiconductor memory module of the present embodiment is provided with 64 resistance elements 13, respectively, between eight respective data input/output terminals of the plurality of bare chips 1 (D0 to D7) and 64 data input/output terminals DQ0 to DQ63 provided on module substrate 2. These 64 resistance elements 13 are provided outside of mold resin 8 and are formed so as to be independently removable one by one even after the plurality of bare chips 1 has been integrally covered with mold resin 8.

Here, bare chips 1 (D0 to D7) and good function chips 3 (D′0 to D′7) utilize common data input/output terminals DQ (DQ0 to DQ63) to which their electrical wires 20, respectively, are connected. In addition, data input/output terminals DQ0 to DQ63 are terminals that are connected to other circuits or memories and that are used for input/output of data between these other circuits or memories and bare chips 1 or good function chips 3.

The semiconductor memory module configuration before repair shown in FIG. 6 is not problematic because repair chip 3 is not mounted. Here, in the configuration of the semiconductor memory module after repair shown in FIG. 7, bare chip 1 (D0) and repair chip 3 (D′0) utilize common data input/output terminals DQ0 to DQ63 that are connected to their respective electrical wires 20. Therefore, input/output signals of bare chip 1 (D0) and repair chip 3 (D′0), respectively, collide with each other at data input/output terminals DQ0 to DQ7 in the condition wherein bare chip 1 (D0) and good function chip 3 (D′0) are both electrically connected to data input/output terminals DQ0 to DQ7.

Therefore, in the semiconductor memory module of the embodiment, as shown in FIGS. 6 and 7, resistance elements 13 are provided in electrical wires 20 so that the mode of an electrical wire 20 is converted from the mode wherein a bare chip 1 that has been detected as being defective inputs/outputs data from/to a data input/output terminal DQ to the mode wherein a good function chip 3 inputs/outputs the data from/to data input/output terminal DQ by cutting a resistance element 13, thereby the above described problem is prevented from occurring.

Accordingly, in the case that there are no bare chips 1 that have been detected as being a defective product, it is not necessary to mount good function chips 3 (D′0 to D′7) and it becomes possible to implement a semiconductor memory module wherein a plurality of bare chips 1 are directly mounted on module substrate 2.

In addition, at the time of operation of the semiconductor memory module, the mode of electrical wires 20 is not normally changed, that is to say, resistance elements (fuses) 13 are not cut. Here, resistance elements (fuses) 13 electrically connected to the good function chip mounting provision regions are not necessary and, therefore, may be cut. In this case, data that has been inputted from outside to data output terminals DQ0 to DQ63 is outputted to bare chips 1 (D0 to D7) and data that has been outputted from bare chips 1 (D0 to D7) is inputted to data input/output terminals DQ0 to DQ63 in the semiconductor memory module.

On the other hand, in the case that there is a bare chip 1 that has been detected as being a defective product from among bare chips 1 (D0 to D7) in the semiconductor memory module, a good function chip 3 (D′0 to D′7) is mounted on the rear side of the surface of module substrate 2 wherein bare chips 1 are provided so that the mode of electrical wires 20 is changed. That is to say, in this case, a resistance element (fuse) 13 electrically connected to bare chip 1 that has been detected as being defective is cut. Thereby, data that has been inputted from outside to data input/output terminals DQ0 to DQ63 is outputted to good function chips 3 (D′0 to D′7) and data that has been outputted from good function chips 3 (D′0 to D′7) is inputted to data input/output terminals DQ0 to DQ63.

According to this change in the mode of electrical wires 20, the semiconductor memory module becomes of a condition wherein transmission of data from data input/output terminals DQ to bare chips 1 (D0 to D7) and transmission of data from bare chips 1 (D0 to D7) to data input/output terminals DQ cannot be carried out. Thereby, data is outputted to data input/output terminals DQ0 to DQ7 or data is inputted from data input/output terminals DQ0 to DQ7 in good function chip 3 (D′0) without receiving interference from the operation of bare chips 1. Accordingly, good function chip 3 carries out the functions of defective bare chip 1 so as to substitute defective bare chip 1, thereby the semiconductor memory module can be repaired.

That is to say, the semiconductor memory module of the first embodiment is, in summary, characterized as follows. A plurality of bare chips 1 integrally molded into mold resin 8 is mounted on the surface of module substrate 2 wherein bare chips 1 are mounted. A normal single chip for repairing the semiconductor memory module, in the case that a problem occurs in a bare chip 1, is mounted on a portion of the rear surface of module substrate 2 wherein the bare chips are mounted.

In addition, in the semiconductor memory module of the present embodiment, the mode of electrical wires 20, that is to say, of jumper circuits 30, is changed in the case that a bare chip 1 is detected as being defective from among the plurality of bare chips 1 so that the data that has been inputted/outputted between data input/output terminals DQ0 to DQ63 and bare chip 1 detected as being defective is switched to be inputted/outputted between data input/output terminals DQ0 to DQ63 and good function chip 3.

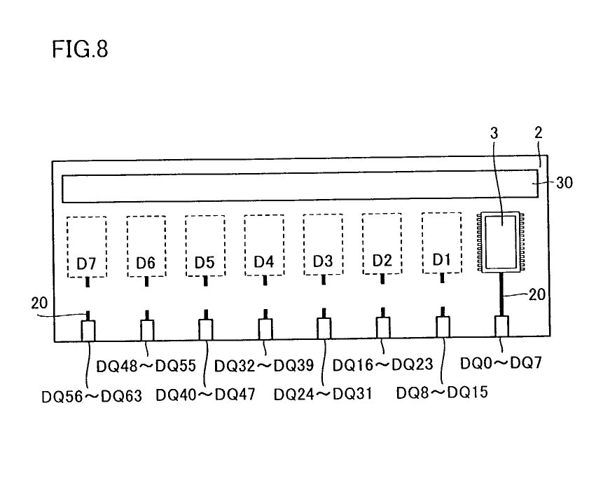

These jumper circuits 30, that is to say, portions of electrical wires 20 to which resistance elements 13, shown in FIGS. 6 and 7, are connected, are mounted on the rear surface of module substrate 2, as shown in FIG. 8, and are circuits for allowing, in the case that bare chip 1 becomes a defective product, good function chip 3 for repair mounted on the rear surface to function in place of bare chip 1 that have become defective.

In addition, good function chips 3 are mounted, in the case that bare chips 1 are detected as being defective from among the plurality of bare chips 1, only in the mounting regions provided on the rear surface of module substrate 2 corresponding to bare chips 1 wherein defects have occurred. Therefore, it becomes possible to minimize the number of good function chips 3 necessary for repairing the semiconductor memory module.

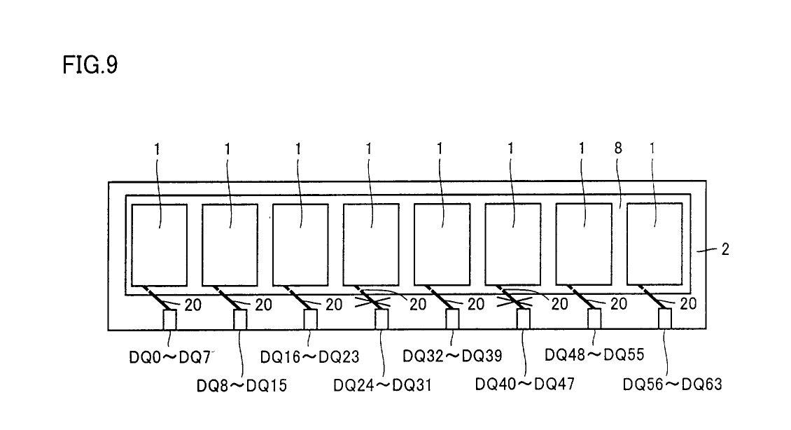

Next, the above described change in the mode of jumper circuits 30 will be described in further detail in reference to FIGS. 9 to 12.

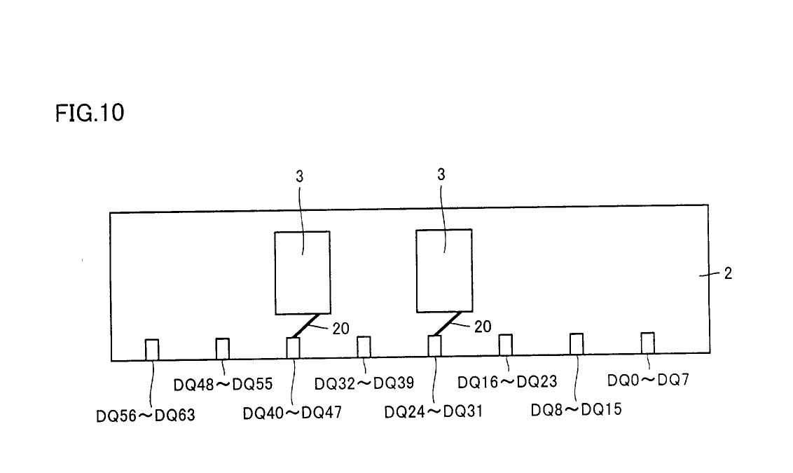

First, before describing the concrete configuration of jumper circuit 30, a summary of the method for repairing a semiconductor memory module of the present embodiment will be described in reference to FIGS. 9 and 10.

As shown in FIG. 9, in the case that two bare chips 1 are detected as being defective from among eight bare chips mounted on the surface of module substrate 2, the electrical connections between these two bare chips 1 and data input/output terminals DQ are cut by removing resistance elements 13 provided outside of mold resin 8. Thereby, two bare chips 1, respectively, which have become defective, cannot input/output data from/to data input/output terminals DQ.

Next, as shown in FIG. 10, two good function chips 3 for repair are mounted on the rear surface of module substrate 2. These two good function chips 3, respectively, are electrically connected to two data input/output terminals DQ, respectively, to which two bare chips 1, respectively, which have been detected as being defective, are electrically connected. Thereby, it becomes possible for two good function chips 3, respectively, to input/output data from/to two data input/output terminals DQ, respectively, to which two bare chips 1, respectively, that have been detected as being defective are connected without receiving interference from the input/output of data of two bare chips 1 that have become defective.

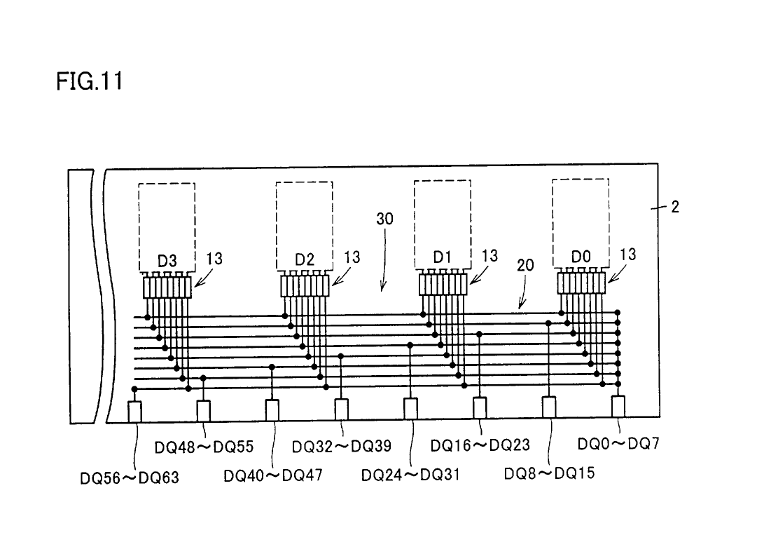

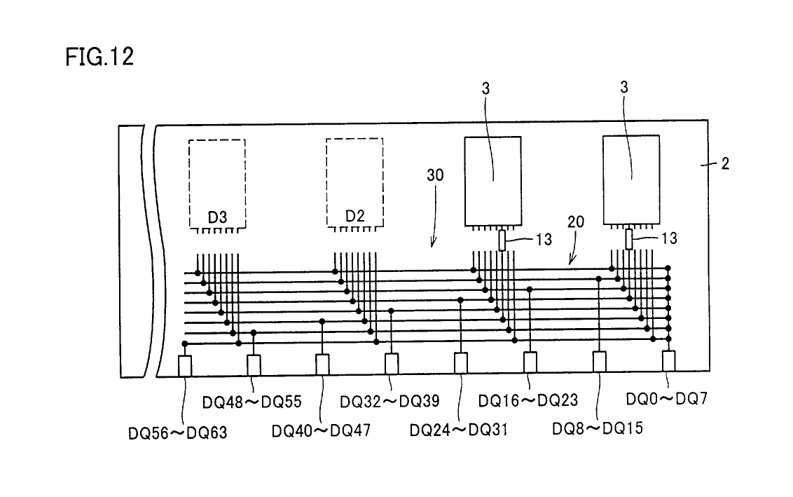

Next, the mode before repair and the mode after repair of jumper circuits 30 on the rear surface of module substrate 2 will be described in detail in reference to FIGS. 11 and 12. Here, FIGS. 11 and 12 show diagrams wherein eight electrical wires 20 are connected to the good function chip mounting provision regions and each of eight electrical wires 20 is depicted as a set of eight electrical wires 20 shown in FIGS. 6 and 7. That is to say, in FIGS. 11 and 12, electric wires 20 are provided outside of the good function chip mounting provision regions so as to form eight routes that connect good function chips 3 and data input/output terminals DQ.

Here, electrical wires 20 are formed so that a resistance element 13 provided in one route connected to data input/output terminal DQ that is to be connected from eight routes is solely made to remain and resistance elements 13 other than the resistance elements 13 provided in other routes can be removed. Therefore, the semiconductor memory module can be repaired regardless of the good function chip mounting regions on the rear surface of module substrate 2 in which good function chips 3 are mounted.

As shown in FIG. 11, electrical wires 20 are connected to eight good function chip mounting provision regions, respectively, in which good function chips 3 are mounted, and resistance elements 13 are provided in these electrical wires 20, before repair.

In addition, as shown in FIG. 12, two good function chips 3 are provided on the rear surface of the module substrate after repair and the resistance elements other than two resistance elements 13 connected to electrical wires 20 for electrically connecting these two good function chips 3, respectively, to two data input/output terminals DQ24 to DQ31 and DQ40 to DQ47, respectively, connected to two bare chips 1 that have been detected as being defective have been removed. In addition, eight resistance elements 13 of eight electrical wires 20 connected to bare chip 1 (for example, D0 in FIG. 7) that has been detected as being defective have also been removed.

Thus, by removing unnecessary resistance elements 13, it becomes possible for good function chip 3 to input/output data to/from data input/output terminal DQ connected to bare chip 1 that has been detected as being defective without interfering with the input/output of data of bare chips 1, which function properly.

Here, as for the semiconductor memory module of the present embodiment, though an example is shown wherein bare chips 1 are mounted on one (front surface) of the surfaces of module substrate 2 while good function chips 3 are mounted on the other surface (rear surface), both bare chips and good function chips may be mounted on one of the surfaces, alone, of a module substrate, so that no chips are mounted on the other side, in the case that a large module substrate can be used.

In addition, though single chips, wherein single bare chips are molded into resin, are used as good function chips 3 in the semiconductor memory module of the present embodiment, chips wherein the plurality of bare chips are integrally molded into mold resin may be used.

(Second Embodiment)

Next, in reference to FIGS. 6, 7 and 13 to 15, a semiconductor memory module of the second embodiment will be described.

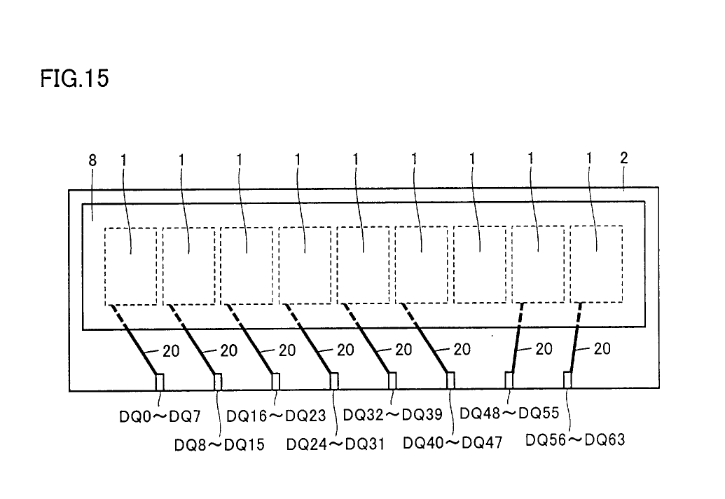

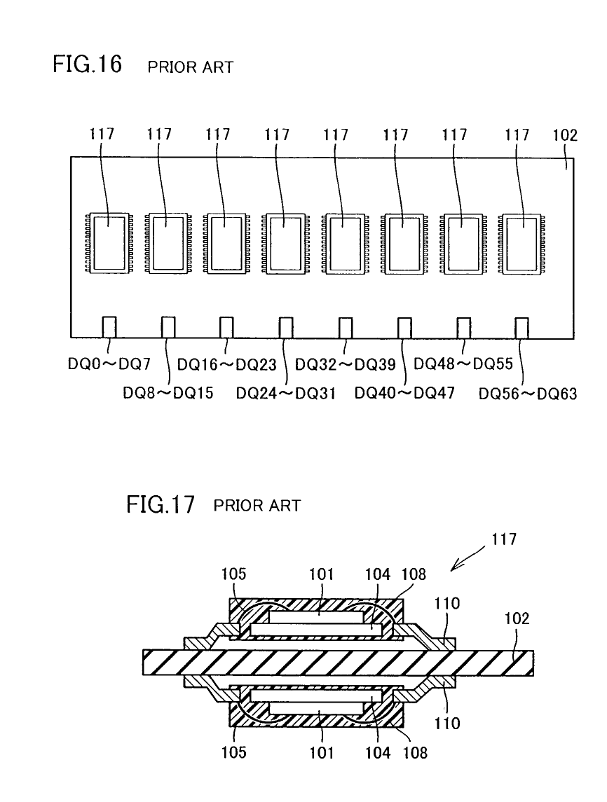

The semiconductor memory module of the present embodiment is, as shown in FIG. 15, a semiconductor memory module wherein a plurality of bare chips 1 is directly mounted on one of the main surfaces of module substrate 2 and the plurality of bare chips 1 is integrally molded into a mold resin 8.

In addition, data input/output terminals of the plurality of bare chips, respectively, are provided on module substrate 2 and are electrically connected to data input/output terminals DQ0 to DQ7, DQ8 to DQ15, DQ16 to DQ23, DQ24 to DQ31, DQ32 to DQ39, DQ40 to DQ47, DQ48 to DQ55 and DQ56 to DQ63 for inputting/outputting data stored in memory regions inside of bare chips 1 from/to the outside of the module substrate.

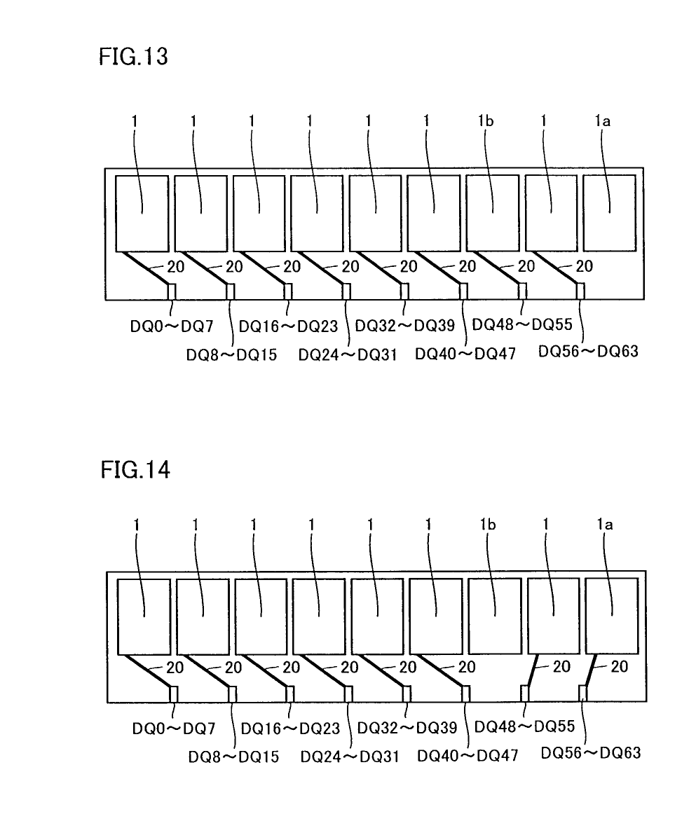

Here, data input/output terminals DQ0 to DQ7, DQ8 to DQ15, DQ16 to DQ23, DQ24 to DQ31, DQ32 to DQ39, DQ40 to DQ47, DQ48 to DQ55 and DQ56 to DQ63, respectively, are depicted as single data input/output terminals in FIGS. 13 to 15. In actuality, however, as shown in FIGS. 6 and 7, there are eight data input/output terminals, connected to eight data lines, respectively, in a one-to-one manner, that are connected to eight data input/output terminals of a bare chip 1 per one data input/output terminal DQ shown in FIG. 1.

The semiconductor memory module of the present embodiment is a semiconductor memory module wherein a memory capacity equal to that of N (for example, N=8) bare chips 1 is required. In addition, in the semiconductor memory module of the present embodiment, as shown in FIG. 15, N+1 bare chips are mounted on module substrate 2 and these N+1 bare chips 1, together with the main surface of module substrate 2, are integrally covered with mold resin 8.

Here, though the semiconductor memory module of the present embodiment is described wherein bare chips are used as memories mounted on module substrate 2, single chips wherein single bare chips are covered with resin may be used in place of the bare chips. In addition, though an example is shown as the semiconductor memory module of the present embodiment wherein bare chips are mounted on only one of the surfaces of module substrate 2, bare chips may be mounted on both the rear surface and the front surface of module substrate 2.

In the semiconductor memory module of the present embodiment, as shown in FIG. 13, N+1 bare chips 1 are mounted on one of the main surfaces of module substrate 2. Here, N is the number of bare chips necessary for obtaining the memory capacity assumed as required for the semiconductor memory module.

In addition, immediately after the N+1 bare chips are mounted on module substrate 2, N bare chips 1 out of N+1 bare chips, respectively, are electrically connected to data input/output terminals DQ in a one-to-one manner while one bare chip 1a out of N+1 bare chips is not electrically connected to data input/output terminal DQ.

This one bare chip 1a, out of N+1 bare chips 1, that is not electrically connected to data input/output terminal DQ is a spare bare chip and is covered with mold resin 8 as an extra good product in the case that a defective product is not detected from among the N+1 bare chips.

Accordingly, even in the case that one bare chip 1b is detected as being defective from among the N+1 bare chips, a semiconductor memory module having the memory capacity of N bare chips 1 can be obtained when spare bare chip 1a can be utilized in place of this bare chip 1b that has been detected as being defective, as shown in FIG. 14.

Here, though N+1 bare chips are mounted in the case wherein the memory capacity of N bare chips is required in the semiconductor memory module of the present embodiment, (N+plural number (M)) bare chips may be mounted taking the probability of occurrence of defective products into consideration. In the case that a plurality of spare bare chips is provided in such a manner, the completed semiconductor memory module has, depending on the number of defective bare chips, three conditions: the condition wherein bare chips 1 that are not connected to data input/output terminals DQ include only defective products; the condition wherein bare chips 1 that are not connected to data input/output terminals DQ include only good products; or the condition wherein bare chips 1 that are not connected to data input/output terminals DQ include both defective products and good products.

The above described method for repairing a semiconductor memory module of the present embodiment will be more concretely described as follows.

In the case that, for example, as shown in FIG. 13, one or less defective products are included in nine bare chips 1, 1a and 1b that have been mounted in advance, electrical connection between one bare chip 1b that has been detected as being a defective product and data input/output terminal DQ to which this bare chip 1b has been electrically connected is cut as shown in FIG. 14. In addition, the status of connections of the electrical wires between nine bare chips 1, 1a and 1b and data input/output terminals DQ is changed so that one bare chips 1a that has been provided as a spare and that has not been electrically connected to any of data input/output terminals DQ is electrically connected to any of data input/output terminals DQ. That is to say, eight bare chips 1 and 1a, respectively, out of nine bare chips 1 and excluding defective bare chip 1b, are electrically connected to data input/output terminals DQ in a one-to-one manner.

Thereby, in the case that a semiconductor memory module having the memory capacity of eight bare chips is desired to be manufactured, the yield of the semiconductor memory module can be increased when the yield of one bare chip 1 is 98.4% or less.

A test calculation of yield improvement effects becomes, for example, as follows. The good product expectation A of the semiconductor memory module at the time when nine bare chips 1 are used in the case of N=8, is given as A=P⁸×(9/8) in the conventional semiconductor memory module when the probability of one bare chip being a good product is P.

In the semiconductor memory module of the present embodiment, the formula B=P⁹+₉C₁×P⁸×(1−P)>A is calculated to obtain P⁸×(P−63/64)<0. Here, C indicates the number of combinations of nine bare chips, among which one bare chip has become defective. Accordingly, in the case that the yield of bare chips 1 is less than 63/64≈98.4%, the yield of the semiconductor memory module of this embodiment has increased in comparison with the conventional semiconductor memory module.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory module comprising:
a module substrate;
a plurality of bare chips mounted on a main surface of the module substrate;
a plurality of good function chip mounting regions wherein, in the case that one or plural bare chips from among the plurality of bare chips are detected as being defective, one or plural good function chips that function in place of said one or plural bare chips that have been detected as being defective can be mounted; and
a switching circuit for allowing, in the case that said one or plural good function chips are mounted in one or plural regions from among said plurality of good function chip mounting regions, a mode wherein data is inputted to/outputted from said one or plural bare chips that have been detected as being defective to be converted to a mode wherein the data is inputted to/outputted from the good function chips mounted in said good function chip mounting regions.

2. The semiconductor memory module according to claim 1, wherein
said switching circuit allows the mode wherein data is inputted to/outputted from said one or plural bare chips that have been detected as being defective to be converted to the mode wherein the data is inputted to/outputted from said good function chips by changing the mode of a resistance element.

3. The semiconductor memory module according to claim 1, comprising
a mold resin for integrally covering said plurality of bare chips together with the main surface of said module substrate, wherein
said switching circuit is provided outside of said mold resin.

4. The semiconductor memory module according to claim 1, wherein
said plurality of bare chips is mounted on one of the main surfaces of said module substrate while said good function chips are mounted on the other one of the main surfaces of said module substrate.

5. The semiconductor memory module according to claim 1, wherein
said good function chips are mounted in said good function chip mounting regions.

6. The semiconductor memory module according to claim 1, wherein
any of said good function chips is not mounted in said good function chip mounting regions.

7. The semiconductor memory module according to claim 1, wherein
said good function chips are single chips wherein single bare chips are covered with resin.

8. A semiconductor memory module, comprising:
a module substrate;
a plurality of bare chips mounted on the module substrate; and
a plurality of substrate input/output terminals provided on said module substrate to which a plurality of chip input/output terminals for inputting/outputting data to/from said bare chips, respectively, is able to electrically connect in a one-to-one manner, wherein
said plurality of bare chips includes an unconnected bare chip wherein said plurality of chip input/output terminals is not electrically connected to any of said plurality of substrate input/output terminals.

9. The semiconductor memory module according to claim 8, wherein
the entirety of said plurality of bare chips and a main surface of said module substrate are integrally covered with resin.

10. The semiconductor memory module according to claim 8, wherein
said unconnected bare chip is a bare chip of a defective product that does not function properly.

11. The semiconductor memory module according to claim 8, wherein
said unconnected bare chip is a spare bare chip that functions properly.

12. The semiconductor memory module according to claim 8, having
a plurality of unconnected bare chips of the same type as said unconnected bare chip, wherein
the plurality of unconnected bare chips includes a spare bare chip that functions properly and a bare chip of a defective product that does not function properly.
